(19) United States
(12) Patent Application Publication
(10) Pub. No.: US 2026/0013111 A1
(43) Pub. Date: Jan. 8, 2026

(54) SEMICONDUCTOR MEMORY DEVICE

(71) Applicant: SAMSUNG ELECTRONICS CO., LTD., Suwon-si (KR)

(72) Inventor: Sung Joon PARK, Suwon-si (KR)

(73) Assignee: SAMSUNG ELECTRONICS CO., LTD., Suwon-si (KR)

(21) Appl. No.: 19/194,834

(22) Filed: Apr. 30, 2025

(30) Foreign Application Priority Data
Jul. 2, 2024 (KR) 10-2024-0086691

(51) Int. Cl. H10B 12/00

(52) U.S. Cl. CPC H10B 12/33; H10B 12/05; H10B 12/50

(57) ABSTRACT

Provided is a semiconductor memory device and method of manufacturing same. The semiconductor memory device includes: a contact pattern including a first surface, a second surface, and a sidewall, wherein the first surface and the second surface are opposite to each other in a first direction, and the sidewall connects the first and the second surfaces; a data storage pattern connected to the first surface; a channel pattern on at least part of the sidewall, wherein the channel pattern is connected to the second surface; a bitline on the channel pattern, wherein the bitline is connected to the channel pattern and extends in a second direction; and a wordline on the channel pattern, wherein the wordline extends in a third direction.

### CROSS-REFERENCE TO RELATED APPLICATION

This application is based on and claims priority to Korean Patent Application No. 10-2024-0086691, filed on Jul. 2, 2024 in the Korean Intellectual Property Office, the contents of which are herein incorporated by reference in its entirety.

### BACKGROUND

The present disclosure relates to a semiconductor memory device, and more particularly, to a semiconductor memory device including a vertical channel transistor (VCT).

To meet consumer demands for excellent performance and low cost, increasing the integration density of semiconductor memory devices is necessary. Since the integration density of semiconductor memory devices is a crucial factor in determining the product price, higher integration density is required.

The integration density of two-dimensional (2D) or planar semiconductor memory devices is primarily determined by the area occupied by unit memory cells and is thus greatly influenced by the level of fine patterning technology. However, since ultra-high-cost equipment is needed for miniaturizing patterns, the integration density of 2D semiconductor memory devices, although increasing, remains limited. Accordingly, semiconductor memory devices including vertical channel transistors (VCT), where the channels extend vertically, have been proposed.

### SUMMARY

Provided is a semiconductor memory device with improved integration density and electrical characteristics.

According to an aspect of the disclosure, a semiconductor memory device includes: a contact pattern including a first surface, a second surface, and a sidewall, wherein the first surface and the second surface are opposite to each other in a first direction, and the sidewall connects the first and the second surfaces; a data storage pattern connected to the first surface; a channel pattern on at least part of the sidewall, wherein the channel pattern is connected to the second surface; a bitline on the channel pattern, wherein the bitline is connected to the channel pattern and extends in a second direction; and a wordline on the channel pattern, wherein the wordline extends in a third direction.

According to an aspect of the disclosure, a semiconductor memory device includes: a contact pattern including a first surface and a second surface opposite to each other in a first direction; a data storage pattern connected to the first surface; a channel pattern connected to the second surface; a bitline spaced apart from the contact pattern in the first direction, wherein the bitline is connected to the channel pattern and extends in a second direction; and a wordline on the channel pattern and extending in a third direction, wherein a height, in the first direction, of the channel pattern is greater than a height from the second surface to a lowermost portion of the bitline.

According to an aspect of the disclosure, a semiconductor memory device includes: a peripheral gate structure on a substrate; a contact pattern on the peripheral gate structure, the contact pattern including a first surface, a second surface, and a sidewall, wherein the first and the second surfaces are opposite to each other in a first direction, and wherein the sidewall connects the first and the second surfaces; a data storage pattern connected to the first surface; a channel pattern connected to the second surface, wherein the channel pattern is on a part of the sidewall; a bitline on the channel pattern, wherein the bitline is connected to the channel pattern and extends in a second direction; and a wordline on the channel pattern and extending in a third direction, wherein the channel pattern includes a vertical portion protruding in the first direction from the second surface, a horizontal portion extending along the second surface, and a contact cover portion on the sidewall.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

It should be noted that the effects of the present disclosure are not limited to those described above, and other effects of the present disclosure will be apparent from the following description.

### BRIEF DESCRIPTION OF DRAWINGS

The above and other aspects and features of certain embodiments of the present disclosure will become more apparent from the following description taken in conjunction with the attached drawings, in which:

FIG. 1 is a schematic layout view of a semiconductor memory device according to one or more embodiments;

FIG. 2 is a layout view of the cell array region of FIG. 1;

FIG. 3 is a cross-sectional view taken along lines A-A and B-B of FIG. 2;

FIG. 4 is a cross-sectional view taken along lines C-C and D-D of FIG. 2;

FIG. 5 is an enlarged view of a portion P of FIG. 3;

FIGS. 6 and 8 are plan views for explaining a shape in which a channel pattern is disposed on a contact pattern in FIG. 3;

FIG. 7 is a perspective view illustrating a shape of the channel pattern of FIG. 6;

FIGS. 9, 10, 11 and 12 are diagrams for explaining a semiconductor memory device according to one or more embodiments;

FIG. 13 is a cross-sectional diagram for explaining a semiconductor memory device according to one or more embodiments;

FIG. 14 is a cross-sectional diagram for explaining a semiconductor memory device according to one or more embodiments;

FIG. 15 is a cross-sectional diagram illustrating a semiconductor memory device according to one or more embodiments;

FIG. 16 is a cross-sectional diagram illustrating a semiconductor memory device according to one or more embodiments;

FIGS. 17 and 18 are cross-sectional diagrams for explaining a semiconductor memory device according to one or more embodiments;

FIGS. 19 and 20 are cross-sectional diagrams for explaining a semiconductor memory device according to one or more embodiments;

FIGS. 21, 22, 23 and 24 are diagrams for describing a semiconductor memory device according to one or more embodiments, respectively; and

FIGS. 25 through 36 are intermediate diagrams for describing a method of manufacturing a semiconductor memory device according to one or more embodiments.

### DETAILED DESCRIPTION

It will be understood that, although the terms “first”, “second”, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

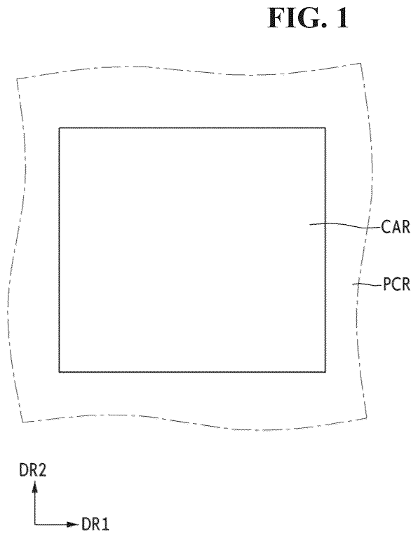

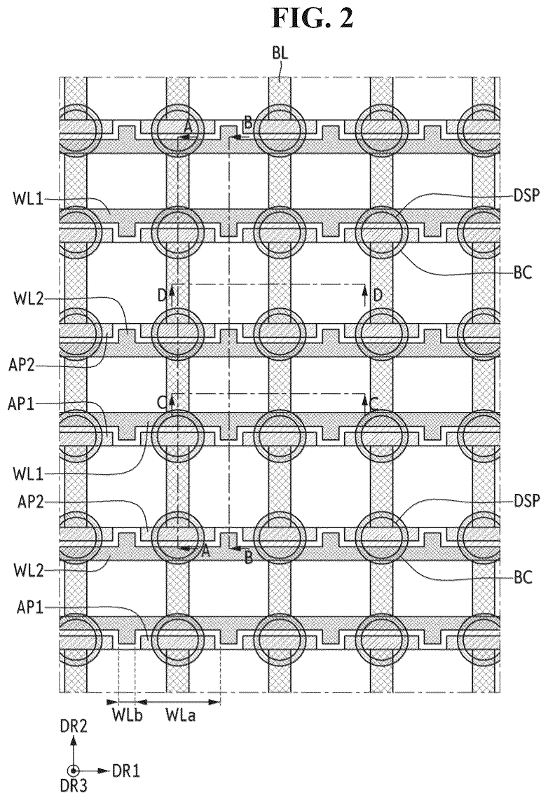

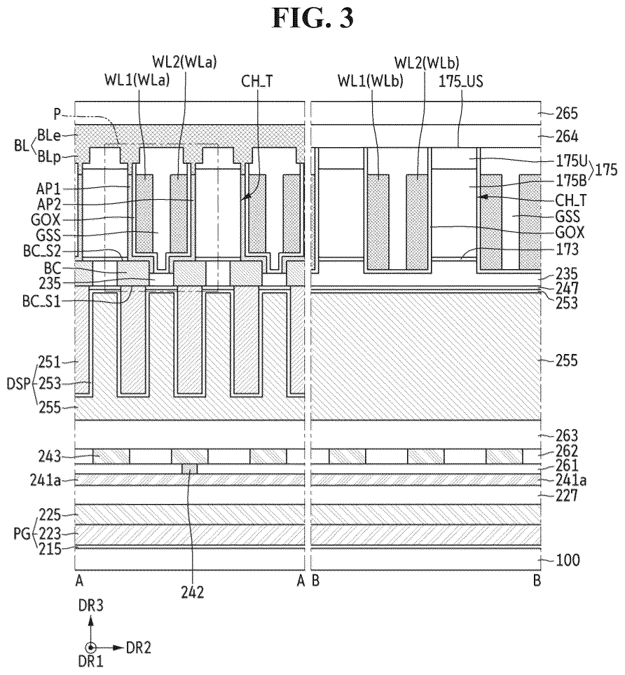

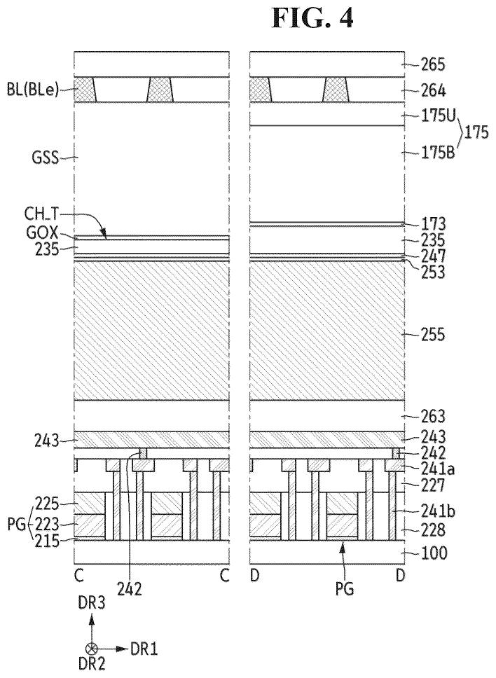

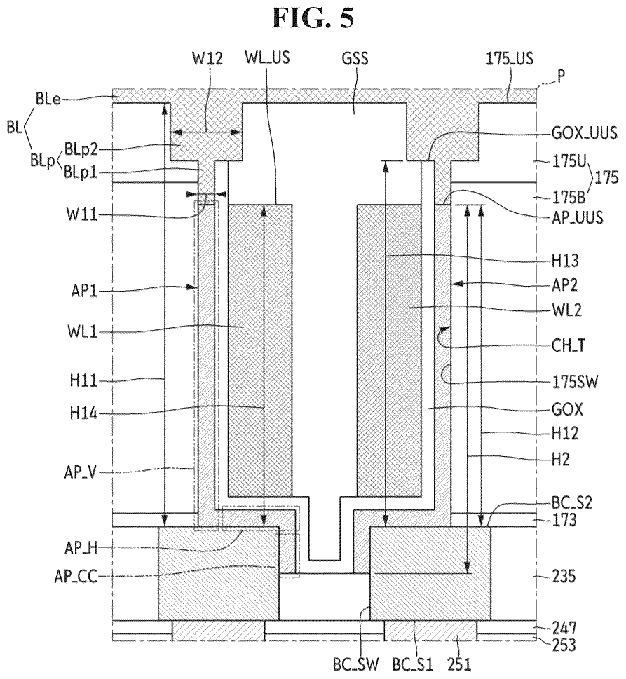

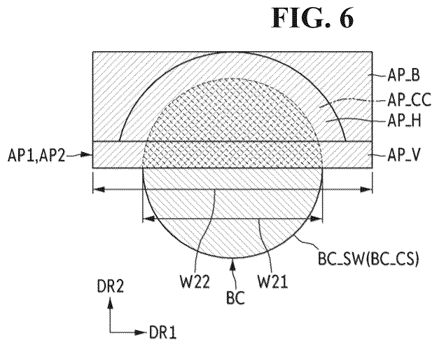

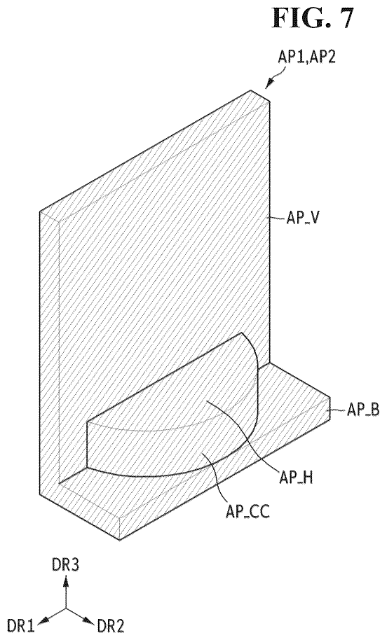

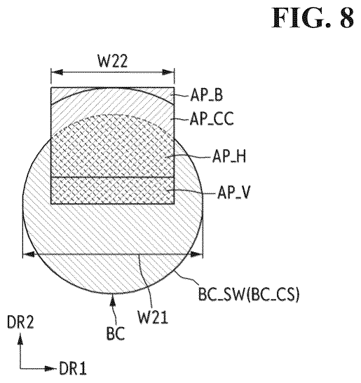

FIG. 1 is a schematic layout view of a semiconductor memory device according to one or more embodiments of the present disclosure. FIG. 2 is a layout view of a cell array area of FIG. 1. FIG. 3 is a cross-sectional view taken along lines A-A and B-B of FIG. 2. FIG. 4 is a cross-sectional view taken along lines C-C and D-D of FIG. 2. FIG. 5 is an enlarged cross-sectional view of part P of FIG. 3. FIGS. 6 and 8 are plan views for explaining the shape in which channel patterns are disposed on contact patterns in FIG. 3. FIG. 7 is a perspective view for explaining the shape of the channel patterns of FIG. 6.

The semiconductor memory device according to one or more embodiments of the present disclosure may include memory cells that include vertical channel transistors (VCTs).

Referring to FIGS. 1 through 7, the semiconductor memory device according to one or more embodiments of the present disclosure may include a peripheral gate structure PG, bitlines BL, wordlines (WL1 and WL2), channel patterns (AP1 and AP2), contact patterns BC, and data storage patterns DSP.

A substrate 100 may include a cell array area CAR where the data storage patterns DSP may be disposed, and a peripheral circuit area PCR that is defined around the cell array area CAR. The substrate 100 may be a silicon substrate, or may include other materials, for example, silicon-germanium, indium antimonide, a lead telluride compound, indium arsenide, indium phosphide, gallium arsenide, or gallium antimonide, but the present disclosure is not limited thereto.

The peripheral gate structure PG may be disposed on the substrate 100. The substrate 100 may include the cell array area CAR and the peripheral circuit area PCR. The peripheral gate structure PG may be arranged over both the cell array area CAR and the peripheral circuit area PCR. In other words, part of the peripheral gate structure PG may be disposed in the cell array area CAR of the substrate 100, and the rest of the peripheral gate structure PG may be disposed in the peripheral circuit area PCR of the substrate 100.

The peripheral gate structure PG may be included in sensing transistors, transfer transistors, and driving transistors. The types of transistors disposed in the cell array area CAR and the peripheral circuit area PCR may vary depending on the design layout of the semiconductor memory device according to one or more embodiments of the present disclosure.

The peripheral gate structure PG may include a peripheral gate insulating film 215, peripheral lower conductive patterns 223, and peripheral upper conductive patterns 225. The peripheral gate insulating film 215 may include a silicon oxide film, a silicon oxynitride film, a high-k dielectric film with a higher dielectric constant than a silicon oxide film, or a combination thereof. The high-k dielectric film may include, for example, at least one of a metal oxide, a metal oxynitride, a metal silicon oxide, and a metal silicon oxynitride, but the present disclosure is not limited thereto.

The peripheral lower conductive patterns 223 and the peripheral upper conductive patterns 225 may each include a conductive material. For example, the peripheral lower conductive patterns 223 and the peripheral upper conductive patterns 225 may each include at least one of a doped semiconductor material, conductive metal nitride, conductive metal silicon nitride, metal carbonitride, conductive metal silicide, conductive metal oxide, a two-dimensional (2D) material, a metal, and a metal alloy. The peripheral gate structure PG is illustrated as including multiple conductive patterns, but the present disclosure is not limited thereto.

In the semiconductor memory device according to one or more embodiments of the present disclosure, the 2D material may be a metallic and/or semiconductor material. The 2D material may include a 2D allotrope or 2D compound, for example, at least one of graphene, molybdenum disulfide (MoS₂), molybdenum diselenide (MoSe₂), tungsten diselenide (WSe₂), and tungsten disulfide (WS₂), but the present disclosure is not limited thereto. That is, these 2D materials are merely illustrative, and the present disclosure is not limited thereto.

A first peripheral lower insulating film 227 and a second peripheral lower insulating film 228 may be disposed on the substrate 100. The first peripheral lower insulating film 227 and the second peripheral lower insulating film 228 may each be formed of an insulating material.

The second peripheral lower insulating film 228 is illustrated as being in contact with the sidewalls of the peripheral lower conductive patterns 223 and the sidewalls of the peripheral upper conductive patterns 225, but the present disclosure is not limited thereto. The peripheral gate structure PG may include peripheral gate spacers disposed on the sidewalls of the peripheral lower conductive patterns 223 and the sidewalls of the peripheral upper conductive patterns 225.

Peripheral wiring lines 241a and the peripheral contact plug 241b may be disposed within the first peripheral lower insulating film 227 and the second peripheral lower insulating film 228, respectively. Peripheral contact plugs 241b may be connected to a source/drain region disposed on at least one side of the peripheral gate structure PG. For example, the source/drain region may be a region doped with impurities in the substrate 100, but the present disclosure is not limited thereto. The peripheral contact plugs 241b may be connected to the peripheral conductive patterns (223 and 225) of the peripheral gate structure PG.

The peripheral wiring lines 241a may be disposed on the peripheral contact plugs 241b. The peripheral wiring lines 241a may be connected to the peripheral contact plugs 241b. For example, the peripheral wiring lines 241a may be wiring lines closest to the peripheral gate structure PG in a third direction DR3.

The peripheral wiring lines 241a and the peripheral contact plugs 241b are illustrated as being different layers, but the present disclosure is not limited thereto. The boundaries between the peripheral wiring lines 241a and the peripheral contact plugs 241b may not be distinguishable. The peripheral wiring lines 241a and the peripheral contact plugs 241b each include a conductive material.

A first peripheral upper insulating film 261 and a second peripheral upper insulating film 262 may be disposed on the peripheral wiring lines 241a and the peripheral contact plugs 241b. The first and second peripheral upper insulating films 261 and 262 may each be formed of an insulating material.

Peripheral connection wirings 243 and peripheral connection vias 242 may be disposed on the peripheral wiring lines 241a. The peripheral connection vias 242 may be disposed within the first peripheral upper insulating film 261. The peripheral connection wirings 243 may be disposed within the second peripheral upper insulating film 262.

The peripheral connection wirings 243 and the peripheral connection vias 242 may be connected to the peripheral wiring lines 241a. The peripheral connection vias 242 may connect the peripheral wiring lines 241a and the peripheral connection wirings 243. The peripheral connection wirings 243 and the peripheral connection vias 242 may each include a conductive material. The peripheral connection wirings 243 and the peripheral connection vias 242 are illustrated as being different layers, but the present disclosure is not limited thereto. The boundaries between the peripheral connection wirings 243 and the peripheral connection vias 242 may not be distinguishable.

Peripheral connection wirings 243 disposed at a single metal level are illustrated as being arranged on the peripheral wiring lines 241a, but the present disclosure is not limited thereto. Alternatively, multiple peripheral connection wirings 243 disposed at different metal levels may be arranged on the peripheral wiring line 241a.

A first interlayer insulating film 263 may be disposed on the peripheral connection wirings 243. The first interlayer insulating film 263 may include an insulating material.

The data storage patterns DSP may be disposed on the first interlayer insulating film 263. The first interlayer insulating film 263 may be disposed between the data storage patterns DSP and the peripheral connection wirings 243.

The data storage patterns DSP may be electrically connected respectively to first channel patterns AP1 and second channel patterns AP2. As illustrated in FIG. 2, the data storage patterns DSP may be arranged in a matrix form along a first direction DR1 and a second direction DR2.

Here, the first and second directions DR1 and DR2 may be orthogonal to the third direction DR3. The first direction DR1 may intersect the second direction DR2. For example, the third direction DR3 may be the thickness direction of the substrate 100. The first and second directions DR1 and DR2 may be parallel to the upper surface of the substrate 100.

For example, the data storage patterns DSP may be capacitors. The data storage patterns DSP may include a capacitor dielectric film 253, which is interposed between storage electrodes 251 and plate electrodes 255. From a planar perspective, the storage electrodes 251 may have various shapes such as circular, elliptical, rectangular, square, rhombic, and hexagonal. The storage electrodes 251 may penetrate a first etch stop film 247. The first etch stop film 247 may be formed of an insulating material.

The storage electrodes 251 and the plate electrodes 255 may each include at least one of, for example, conductive semiconductor material, conductive metal nitride, conductive metal silicon nitride, metal carbonitride, conductive metal silicide, conductive metal oxide, and a metal. The capacitor dielectric film 253 may include at least one of a ferroelectric material, an antiferroelectric material, and a paraelectric material. For example, the capacitor dielectric film 253 may include one of a ferroelectric material, an antiferroelectric material, a paraelectric material, a combination of the ferroelectric and antiferroelectric materials, a combination of the ferroelectric and paraelectric materials, a combination of the paraelectric and antiferroelectric materials, or a combination of the ferroelectric, antiferroelectric, and paraelectric materials.

Alternatively, the data storage patterns DSP may be variable resistance patterns that can switch between two resistance states in response to electrical pulses applied to memory elements. For example, the data storage patterns DSP may include a phase-change material that changes its crystalline state based on the amount of current, a perovskite compound, transition metal oxide, a magnetic material, a ferromagnetic material, or an antiferromagnetic material.

The contact patterns BC may be disposed on the data storage patterns DSP. The contact patterns BC may be disposed on the storage electrodes 251. The storage electrodes 251 may contact the contact patterns BC. From a planar perspective, the contact patterns BC may have various shapes such as circular, elliptical, rectangular, square, rhombic, and hexagonal.

A contact separation insulating film 235 may be disposed on the first etch stop film 247. The contact separation insulating film 235 may be disposed between the contact patterns BC. From a planar perspective, the contact patterns BC may be arranged in a matrix form along the first and second directions DR1 and DR2. The contact separation insulating film 235 may be formed of an insulating material.

Each of the contact patterns BC may include a first surface BC_S1 and a second surface BC_S2, which are opposite to each other in the third direction DR3. Each of the contact patterns BC may also include sidewalls BC_SW, which connect the first and second surfaces BC_S1 and BC_S2. From a planar perspective, the sidewalls BC_SW of the contact patterns BC may define outer circumferential surfaces BC_CS of the contact patterns BC.

The first surfaces BC_S1 of the contact patterns BC may face the data storage patterns DSP. The data storage patterns DSP may be connected to the first surfaces BC_S1 of the contact patterns BC. The storage electrodes 251 may contact the first surfaces BC_S1 of the contact patterns BC.

The contact separation insulating film 235 may cover the sidewalls BC_SW of the contact patterns BC. For example, the contact separation insulating film 235 may not cover the entire sidewalls BC_SW of the contact patterns BC. In other words, parts of the sidewalls BC_SW of the contact patterns BC may not be covered by the contact separation insulating film 235. Other parts of the sidewalls BC_SW of the contact patterns BC may be covered by the contact separation insulating film 235.

The data storage patterns DSP may completely or partially overlap with the contact patterns BC in the third direction DR3. The data storage patterns DSP may contact all or parts of the first surfaces BC_S1 of the contact patterns BC.

The contact patterns BC may include a conductive material. For example, the contact patterns BC may include at least one of doped polysilicon, conductive metal nitride, conductive metal silicon nitride, metal carbon nitride, conductive metal silicide, conductive metal oxide, a 2D material, a metal, and a metal alloy.

Protruding insulating patterns 175 may be disposed on the contact patterns BC and the contact separation insulating film 235. A second etch stop film 173 may be disposed between the protruding insulating patterns 175 and the contact separation insulating film 235.

The protruding insulating patterns 175 may include upper protruding insulating patterns 175U and lower protruding insulating patterns 175B. The lower protruding insulating patterns 175B may be disposed between the upper protruding insulating patterns 175U and the contact patterns BC, and between the upper protruding insulating patterns 175U and the contact separation insulating film 235. The lower protruding insulating patterns 175B may be disposed between the upper protruding insulating patterns 175U and the second etch stop film 173. The upper protruding insulating patterns 175U may include upper surfaces 175_US of the protruding insulating patterns 175.

The upper protruding insulating patterns 175U and the lower protruding insulating patterns 175B may each be formed of an insulating material. The upper protruding insulating patterns 175U and the lower protruding insulating patterns 175B may include different insulating materials. In the semiconductor memory device according to one or more embodiments of the present disclosure, the upper protruding insulating patterns 175U may include silicon nitride, and the lower protruding insulating patterns 175B may include silicon oxide.

The second etch stop film 173 may be formed of an insulating material. The second etch stop film 173 may include a material having an etch selectivity with respect to the lower protruding insulating patterns 175B. Alternatively, the second etch stop film 173 may not be disposed between the lower protruding insulating patterns 175B and the contact separation insulating film 235.

The protruding insulating patterns 175 are illustrated as having a double-layer structure, but the present disclosure is not limited thereto. Alternatively, the protruding insulating pattern 175 may have a single-layer structure. If the protruding insulating patterns 175 have a single-layer structure, the protruding insulating patterns 175 may include silicon oxide, but the present disclosure is not limited thereto. Alternatively, the protruding insulating patterns 175 may have a triple-layer structure (or a structure including more than three layers). In this example, the protruding insulating patterns 175 may have a laminated insulating film structure where silicon oxide, silicon nitride, and silicon oxide are stacked, but the present disclosure is not limited thereto.

The protruding insulating patterns 175 may include a plurality of channel trenches CH_T. The channel trenches CH_T may extend in the first direction DR1. Each pair of adjacent channel trenches CH_T may be spaced apart in the second direction DR2.

The channel trenches CH_T may expose the contact patterns BC. The second surfaces BC_S2 of the contact patterns BC may be exposed by the channel trenches CH_T. For example, parts of the second surfaces BC_S2 of the contact patterns BC may be exposed by the channel trenches CH_T.

In the areas where the contact patterns BC overlap with the channel trenches CH_T in the third direction DR3, the contact separation insulating film 235 may not cover parts of the sidewalls BC_SW of the contact patterns BC. The uncovered parts of the sidewalls BC_SW of the contact patterns BC may be located where the channel trenches CH_T overlap with the contact patterns BC in the third direction DR3.

The bottom surfaces of the channel trenches CH_T may be defined by the contact patterns BC and the contact separation insulating film 235. The bottom surfaces of the channel trenches CH_T may have a concave-convex shape. Based on the first surfaces BC_S1 of the contact patterns BC, the portions of the bottom surfaces of the channel trenches CH_T defined by the second surfaces BC_S2 of the contact patterns BC may be higher than the portions of the bottom surfaces of the channel trenches CH_T defined by the contact separation insulating film 235.

The contact separation insulating film 235 may include first regions that overlap with the channel trenches CH_T in the third direction DR3, and second regions that do not overlap with the channel trenches CH_T in the third direction DR3. The contact separation insulating film 235 may include a first surface and a second surface opposite to each other in the third direction DR3. The first surface of the contact separation insulating film 235 may face the data storage patterns DSP. Relative to the first surface of the contact separation insulating film 235, the second surface of the contact separation insulating film 235 is lower in the first regions than in the second regions.

The sidewalls of the channel trenches CH_T may be defined by the lower protruding insulating patterns 175B, the upper protruding insulating patterns 175U, and the second etch stop film 173. At least parts of the sidewalls of the channel trenches CH_T may be sidewalls 175SW of the protruding insulating patterns 175. If the second etch stop film 173 is not present, the sidewalls of the channel trenches CH_T may be defined by the lower protruding insulating patterns 175B and the upper protruding insulating patterns 175U.

The first channel patterns AP1 and the second channel patterns AP2 may be disposed on the data storage patterns DSP. The data storage patterns DSP may be disposed between the first channel patterns AP1 and the substrate 100. The data storage patterns DSP may be disposed between the second channel patterns AP2 and the substrate 100.

The first channel patterns AP1 and the second channel patterns AP2 may be disposed on the contact patterns BC. The first channel patterns AP1 and the second channel patterns AP2 may be connected to the contact patterns BC, respectively. The first channel patterns AP1 and the second channel patterns AP2 may be connected to the second surfaces BC_S2 of the contact patterns BC, respectively.

The first channel patterns AP1 may be spaced apart from one another in the first direction DR1. The first channel patterns AP1 may be spaced apart at regular intervals. The second channel patterns AP2 may be spaced apart from one another in the first direction DR1. The second channel patterns AP2 may be spaced apart at regular intervals. The first channel patterns AP1 may be spaced apart from the second channel patterns AP2 in the second direction DR2. The first channel patterns AP1 and the second channel patterns AP2 may be arranged two-dimensionally along the first and second directions DR1 and DR2.

The first channel patterns AP1 and the second channel patterns AP2 may be disposed within the channel trenches CH_T that extend in the first direction DR1. A plurality of first channel patterns AP1 may be disposed within a single channel trench CH_T. A plurality of second channel patterns AP2 may be disposed within a single channel trench CH_T.

The first channel patterns AP1 and the second channel patterns AP2 may cover parts of the sidewalls BC_SW of the contact patterns BC. The first channel patterns AP1 and the second channel patterns AP2 may extend in the third direction DR3 along the sidewalls BC_SW of the contact patterns BC. The first channel patterns AP1 and the second channel patterns AP2 may not extend to the first surfaces BC_S1 of the contact patterns BC.

In the semiconductor memory device according to one or more embodiments of the present disclosure, the first channel patterns AP1 and the second channel patterns AP2 may each include a vertical portion AP_V, a horizontal portion AP_H, a contact cover portion AP_CC, and a bottom portion AP_B.

The vertical portions AP_V of the channel patterns (AP1 and AP2) may protrude in the third direction DR3 from the second surfaces BC_S2 of the contact patterns BC. The vertical portions AP_V of the channel patterns (AP1 and AP2) may extend along the sidewalls of the channel trenches CH_T. The vertical portions AP_V of the channel patterns (AP1 and AP2) may extend along the sidewalls 175SW of the protruding insulating patterns 175.

The horizontal portions AP_H of the channel patterns (AP1 and AP2) may extend along the second surfaces BC_S2 of the contact patterns BC. The horizontal portions AP_H of the channel patterns (AP1 and AP2) may be directly connected to the vertical portions AP_V of the channel patterns (AP1 and AP2). From a cross-sectional perspective, the horizontal portions AP_H of the channel patterns (AP1 and AP2) may protrude in the second direction DR2 from the vertical portions AP_V.

The contact cover portions AP_CC of the channel patterns (AP1 and AP2) may be disposed on the sidewalls BC_SW of the contact patterns BC. The contact cover portions AP_CC of the channel patterns (AP1 and AP2) may extend in the third direction DR3 along the sidewalls BC_SW of the contact patterns BC. The contact cover portions AP_CC of the channel patterns (AP1 and AP2) may not extend to the first surfaces BC_S1 of the contact patterns BC.

The contact cover portions AP_CC of the channel patterns (AP1 and AP2) may cover the sidewalls BC_SW of the contact patterns BC. For example, the contact cover portions AP_CC of the channel patterns (AP1 and AP2) may cover parts of the sidewalls BC_SW of the contact patterns BC.

From a planar perspective, the contact cover portions AP_CC of the channel patterns (AP1 and AP2) may extend along the outer circumferential surfaces BC_CS of the contact patterns BC. For example, the contact cover portions AP_CC of the channel patterns (AP1 and AP2) may extend along parts of the outer circumferential surfaces BC_CS of the contact patterns BC. The contact cover portions AP_CC of the channel patterns (AP1 and AP2) do not extend along the rest of the outer circumferential surfaces BC_CS of the contact patterns BC.

The bottom portions AP_B of the channel patterns (AP1 and AP2) may be disposed on the second surface of the contact separation insulating film 235. The bottom portions AP_B may extend along the second surface of the contact separation insulating film 235.

In FIG. 6, a width W22, in the first direction DR1, of the channel patterns (AP1 and AP2) may be greater than a width W21, in the first direction DR1, of the second surfaces BC_S2 of the contact patterns BC.

In FIG. 8, the width W22 of the channel patterns (AP1 and AP2) may be less than or equal to the width W21 of the second surfaces BC_S2 of the contact patterns BC. The perspective view of the shape of the channel patterns (AP1 and AP2) of FIG. 8 may be similar to that shown in FIG. 6.

The first channel patterns AP1 and the second channel patterns AP2 may each include an oxide semiconductor material. The first channel patterns AP1 and the second channel patterns AP2 may include, for example, a metal oxide. For example, the first channel patterns AP1 and the second channel patterns AP2 may be amorphous metal oxide films. In another example, the first channel patterns AP1 and the second channel patterns AP2 may be polycrystalline metal oxide films. In yet another example, the first channel patterns AP1 and the second channel patterns AP2 may be a combination of amorphous metal oxide films and polycrystalline metal oxide films. In still another example, the first channel patterns AP1 and the second channel patterns AP2 may be c-axis aligned crystalline (CAAC) metal oxide films.

The first channel patterns AP1 and the second channel patterns AP2 may include, for example, indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, or In—Hf—Al—Zn-based oxide, but the present disclosure is not limited thereto.

Here, In—Ga—Zn-based oxide refers to an oxide having In, Ga, and Zn as its main components, but not necessarily the ratio of In, Ga, and Zn. For example, the channel structures AP_ST may include InₓGa_{y}Zn_{z}O. IGZO (In:Ga:Zn=1:1:1) with In, Ga, and Zn included in the same ratios may be an In—Ga—Zn-based oxide. Ga-rich IGZO has a higher Ga ratio and a lower In ratio than IGZO (In:Ga:Zn=1:1:1). Ga-rich IGZO may also be an In—Ga—Zn-based oxide. Additionally, In-rich IGZO has a higher In ratio and a lower Ga ratio than IGZO (In:Ga:Zn=1:1:1). In-rich IGZO may also be an In—Ga—Zn-based oxide.

The first channel patterns AP1 and the second channel patterns AP2 have been described above as including IGZO, but the present disclosure is not limited thereto. The above description may also be applicable if the first channel patterns AP1 and the second channel patterns AP2 each include a ternary or higher metal oxide. Additionally, if the first channel patterns AP1 and the second channel patterns AP2 include an In—Ga—Zn-based oxide, the first channel patterns AP1 and the second channel patterns AP2 may further include a doped metal element other than In, Ga, and Zn.

The first wordlines WL1 may be disposed on the first channel patterns AP1. The second wordlines WL2 may be disposed on the second channel patterns AP2. The first wordlines WL1 and the second wordlines WL2 may be disposed within the channel trenches CH_T.

The first wordlines WL1 and the second wordlines WL2 may extend in the first direction DR1. The first wordlines WL1 and the second wordlines WL2 may be alternately arranged in the second direction DR2. The first wordlines WL1 may be spaced apart from the second wordlines WL2 in the second direction DR2.

The first wordlines WL1 and the second wordlines WL2 may be spaced apart from the bitlines BL in the third direction DR3. The first wordlines WL1 and the second wordlines WL2 intersect the bitlines BL. The first wordlines WL1 and the second wordlines WL2 may be spaced apart from the contact patterns BC in the third direction DR3.

The first wordlines WL1 and the second wordlines WL2 may be disposed on the horizontal portions AP_H of the channel patterns (AP1 and AP2). The first wordlines WL1 and the second wordlines WL2 may be disposed between the vertical portions AP_V of the first channel patterns AP1 and the vertical portions AP_V of the second channel patterns AP2.

The first wordlines WL1 and the second wordlines WL2 may be disposed between the first channel patterns AP1 and the second channel patterns AP2. The first channel patterns AP1 may be closer to the first wordlines WL1 than to the second wordlines WL2. The second channel patterns AP2 may be closer to the second wordlines WL2 than to the first wordlines WL1.

The first wordlines WL1 and the second wordlines WL2 may have a width in the second direction DR2. The width of the first wordlines WL1 may differ between the areas where the first channel patterns AP1 and the second channel patterns AP2 overlap in the third direction DR3 and the areas where the first channel patterns AP1 and the second channel patterns AP2 may not overlap in the third direction DR3. Similarly, the width of the second wordlines WL2 may differ between the areas where the first channel patterns AP1 and the second channel patterns AP2 overlap in the third direction DR3 and the areas where the first channel patterns AP1 and the second channel patterns AP2 may not overlap in the third direction DR3.

For example, the first wordlines WL1 and the second wordlines WL2 may each include first portions WLa and second portions WLb. The width, in the second direction DR2, of the first portions WLa of the wordlines (WL1 and WL2) may be smaller than the width, in the second direction DR2, of the second portions WLb of the wordlines (WL1 and WL2). For example, the first portions WLa of the wordlines (WL1 and WL2) may be disposed on the first channel patterns AP1 and the second channel patterns AP2.

The first wordlines WL1 and the second wordlines WL2 may each include first portions WLa and second portions WLb that are alternately arranged in the first direction DR1. In the first wordlines WL1, the first channel patterns AP1 may be disposed among the second portions WLb of the wordlines (WL1 and WL2) that are adjacent in the first direction DR1. In the second wordlines WL2, the second channel patterns AP2 may be disposed among the second portions WLb of the wordlines (WL1 and WL2) that are adjacent in the first direction DR1.

Alternatively, the width, in the second direction DR2, of the first portions WLa of the wordlines (WL1 and WL2) may be the same as the width, in the second direction DR2, of the second portions WLb of the wordlines (WL1 and WL2). In this case, a gate insulating film GOX, which will be described later, may fill the space between each pair of adjacent first channel patterns AP1 in the first direction DR1 and the space between each pair of adjacent second channel patterns AP2 in the first direction DR1.

The first channel patterns AP1 and the second channel patterns AP2 may not disposed below the second portions WLb of the wordlines (WL1 and WL2). The height of the first portions WLa of the wordlines (WL1 and WL2) may be less than the height of the second portions WLb of the wordlines (WL1 and WL2). For example, the height difference between the first portions WLa of the wordlines (WL1 and WL2) and the second portions WLb of the wordlines (WL1 and WL2) may be equal to the thickness of the channel patterns (AP1 and AP2).

The first wordlines WL1 and the second wordlines WL2 may include a conductive material, such as doped polysilicon, conductive metal nitride, conductive metal silicon nitride, metal carbonitride, conductive metal silicide, conductive metal oxide, a 2D material, a metal, or a metal alloy.

Each of the first wordlines WL1 and the second wordlines WL2 may include an upper surface WL_US and a lower surface in the third direction DR3. The lower surfaces of the first wordlines WL1 and the second wordlines WL2 face the second surfaces BC_S2 of the contact patterns BC.

In FIG. 5, the upper surfaces WL_US of the wordlines (WL1 and WL2) may be planar. Alternatively, the upper surfaces WL_US of the wordlines (WL1 and WL2) may be convexly rounded. As another alternative, the upper surfaces WL_US of the wordlines (WL1 and WL2) may be concavely rounded.

The following description is provided from the perspective of a cross-sectional view such as FIGS. 3 and 5. Based on the second surfaces BC_S2 of the contact patterns BC, the upper surfaces WL_US of the wordlines (WL1 and WL2) may be equal to or higher than uppermost surfaces AP_UUS of the first channel patterns AP1 and uppermost surfaces AP_UUS of the second channel patterns AP2. A height H12 from the second surfaces BC_S2 of the contact patterns BC to the uppermost surfaces AP_UUS of the channel patterns (AP1 and AP2) may be less than or equal to a height H14 from the second surfaces BC_S2 of the contact patterns BC to the upper surfaces WL_US of the wordlines (WL1 and WL2).

Based on the second surfaces BC_S2 of the contact patterns BC, the uppermost surfaces AP_UUS of the first channel patterns AP1 and the uppermost surfaces AP_UUS of the second channel patterns AP2 may be lower than the upper surfaces 175_US of the protruding insulating patterns 175. The height H12 from the second surfaces BC_S2 of the contact patterns BC to the uppermost surfaces AP_UUS of the channel patterns (AP1 and AP2) is less than a height H11 from the second surfaces BC_S2 of the contact patterns BC to the upper surfaces 175_US of the protruding insulating patterns 175.

The gate insulating film GOX may be disposed between the first wordlines WL1 and the first channel patterns AP1, and between the second wordlines WL2 and the second channel patterns AP2. The gate insulating film GOX may extend in the first direction DR1 parallel to the first wordlines WL1 and the second wordlines WL2.

In a cross-sectional view such as FIG. 5, the horizontal portions AP_H of the channel patterns (AP1 and AP2) may be disposed between the gate insulating film GOX and the contact patterns BC, and thus, the gate insulating film GOX may not contact the second surfaces BC_S2 of the contact patterns BC.

The gate insulating film GOX may extend along the vertical portions AP_V of the channel patterns (AP1 and AP2). From a cross-sectional perspective, the gate insulating film GOX between the first wordlines WL1 and the first channel patterns AP1 may be directly connected to the gate insulating film GOX between the second wordlines WL2 and the second channel patterns AP2. Alternatively, the gate insulating film GOX between the first wordlines WL1 and the first channel patterns AP1 may be separated from the gate insulating film GOX between the second wordlines WL2 and the second channel patterns AP2.

The gate insulating film GOX may include a silicon oxide film, a silicon oxynitride film, a high-k dielectric film with a higher dielectric constant than a silicon oxide film, or a combination thereof. For example, the gate insulating film GOX may include aluminum oxide, but the present disclosure is not limited thereto.

Part of the gate insulating film GOX may protrude in the third direction DR3 beyond the upper surfaces WL_US of the first wordlines WL1 and the upper surfaces WL_US of the second wordlines WL2. Part of the gate insulating film GOX may protrude in the third direction DR3 beyond the uppermost surfaces AP_UUS of the first channel patterns AP1 and the uppermost surfaces AP_UUS of the second channel patterns AP2.

A height H13 from the second surfaces BC_S2 of the contact patterns BC to an uppermost surface GOX_UUS of the gate insulating film GOX may be greater than the height H12 from the second surfaces BC_S2 of the contact patterns BC to the uppermost surfaces AP_UUS of the channel patterns (AP1 and AP2). The height H13 from the second surfaces BC_S2 of the contact patterns BC to the uppermost surface GOX_UUS of the gate insulating film GOX may be greater than the height H14 from the second surfaces BC_S2 of the contact patterns BC to the upper surfaces WL_US of the wordlines (WL1 and WL2).

Gate separation patterns GSS may be disposed between the first wordlines WL1 and the second wordlines WL2 that are adjacent to the first wordlines WL1 in the second direction DR2. The first wordlines WL1 and the second wordlines WL2 may be separated by the gate separation patterns GSS. The gate separation patterns GSS may extend in the first direction DR1 between the first wordlines WL1 and the second wordlines WL2.

The first wordlines WL1 may be disposed between the gate separation patterns GSS and the first channel patterns AP1. The second wordlines WL2 may be disposed between the gate separation patterns GSS and the second channel patterns AP2.

In the semiconductor memory device according to one or more embodiments of the present disclosure, relative to the second surfaces BC_S2 of the contact patterns BC, the upper surfaces of the gate separation patterns GSS may be at the same height as the upper surfaces 175_US of the protruding insulating patterns 175. For example, the gate separation patterns GSS may not be disposed on the upper surfaces 175_US of the protruding insulating patterns 175.

The gate separation patterns GSS may be formed of an insulating material. The gate separation patterns GSS are illustrated as being single layers, but the present disclosure is not limited thereto.

The bitlines BL may be disposed on the first channel patterns AP1 and the second channel patterns AP2. The bitlines BL may be connected to the first channel patterns AP1 and the second channel patterns AP2. The bitlines BL may be connected to the vertical portions AP_V of the first channel patterns AP1. The bitlines BL may be connected to the vertical portions AP_V of the second channel patterns AP2.

The bitlines BL may extend in the second direction DR2. The bitlines BL may be spaced apart from one another in the first direction DR1.

In the semiconductor memory device according to one or more embodiments of the present disclosure, the data storage patterns DSP may be disposed between the peripheral gate structures PG and the bitlines BL.

The bitlines BL may include extension portions BLe and protruding portions BLp. The extension portions BLe of the bitlines BL may extend in the second direction DR2. In the semiconductor memory device according to one or more embodiments of the present disclosure, the width of the extension portions BLe of the bitlines BL in the first direction DR1 may decrease away from the protruding insulating patterns 175 and the gate separation patterns GSS. For example, the extension portions BLe of the bitlines BL may be formed through a subtractive etching process.

The protruding portions BLp of the bitlines BL may protrude in the third direction DR3. The protruding portions BLp of the bitlines BL may protrude from the extension portions BLe of the bitlines BL toward the first channel patterns AP1. The protruding portions BLp of the bitlines BL may protrude from the extension portions BLe of the bitlines BL toward the second channel patterns AP2.

The protruding portions BLp of the bitlines BL may be connected to the first channel patterns AP1 and the second channel patterns AP2. The protruding portions BLp of the bitlines BL may connect the first channel patterns AP1 and the extension portions BLe of the bitlines BL. The protruding portions BLp of the bitlines BL may connect the second channel patterns AP2 and the extension portions BLe of the bitlines BL. Based on the second surfaces BC_S2 of the contact patterns BC, the protruding portions BLp of the bitlines BL may include the lowermost portions of the bitlines BL.

The protruding portions BLp of the bitlines BL may include first sub-protruding portions BLp1 and second sub-protruding portions BLp2.

The first sub-protruding portions BLp1 of the bitlines BL may be connected to the first channel patterns AP1 and the second channel patterns AP2. For example, the first sub-protruding portions BLp1 of the bitlines BL may contact the first channel patterns AP1 and the second channel patterns AP2. For example, from a cross-sectional perspective, the first sub-protruding portions BLp1 of the bitlines BL may be disposed between the gate insulating film GOX and the protruding insulating patterns 175.

The second sub-protruding portions BLp2 of the bitlines BL may be disposed between the first sub-protruding portions BLp1 of the bitlines BL and the extension portions BLe of the bitlines BL. For example, from a cross-sectional perspective, the second sub-protruding portions BLp2 of the bitlines BL may be disposed between the gate separation patterns GSS and the protruding insulating patterns 175.

A width W12, in the second direction DR2, of the second sub-protruding portions BLp2 of the bitlines BL may be greater than a width W11, in the second direction DR2, of the first sub-protruding portions BLp1 of the bitlines BL.

The bitlines BL may include at least one of a doped semiconductor material, conductive metal nitride, conductive metal silicon nitride, metal carbonitride, conductive metal silicide, conductive metal oxide, a 2D material, and a metal. The bitlines BL are illustrated as being single-layered, but the present disclosure is not limited thereto.

In a cross-sectional view such as FIG. 3 or 5, the height H12 from the second surfaces BC_S2 of the contact patterns BC to the uppermost surfaces AP_UUS of the channel patterns (AP1 and AP2) may be the same as the height from the second surfaces BC_S2 of the contact patterns BC to the lowermost parts of the bitlines BL. The height H12 from the second surfaces BC_S2 of the contact patterns BC to the lowermost parts of the bitlines BL may be less than the height H11 from the second surfaces BC_S2 of the contact patterns BC to the upper surfaces 175_US of the protruding insulating patterns 175.

The distance, in the third direction DR3, between the contact patterns BC and the bitlines BL may be the height H12 from the second surfaces BC_S2 of the contact patterns BC to the lowermost parts of the bitlines BL. The height H2 in the third direction DR3 of the channel patterns (AP1 and AP2) may be greater than the distance (i.e., the height H12), in the third direction DR3, between the contact patterns BC and the bitlines BL.

Alternatively, the protruding portions BLp of the bitlines BL may not include the first sub-protruding portions BLp1. In this case, the second sub-protruding portions BLp2 of the bitlines BL may contact the first channel patterns AP1 and the second channel patterns AP2, and the height H13 from the second surfaces BC_S2 of the contact patterns BC to the uppermost surface GOX_UUS of the gate insulating film GOX may be greater than the height H12 from the second surfaces BC_S2 of the contact patterns BC to the uppermost surfaces AP_UUS of the channel patterns (AP1 and AP2).

The extension portions BLe of the bitlines BL may be disposed within a second interlayer insulating film 264. A third interlayer insulating film 265 may be disposed on the bitlines BL and the second interlayer insulating film 264. The second and third interlayer insulating films 264 and 265 may each include an insulating material.

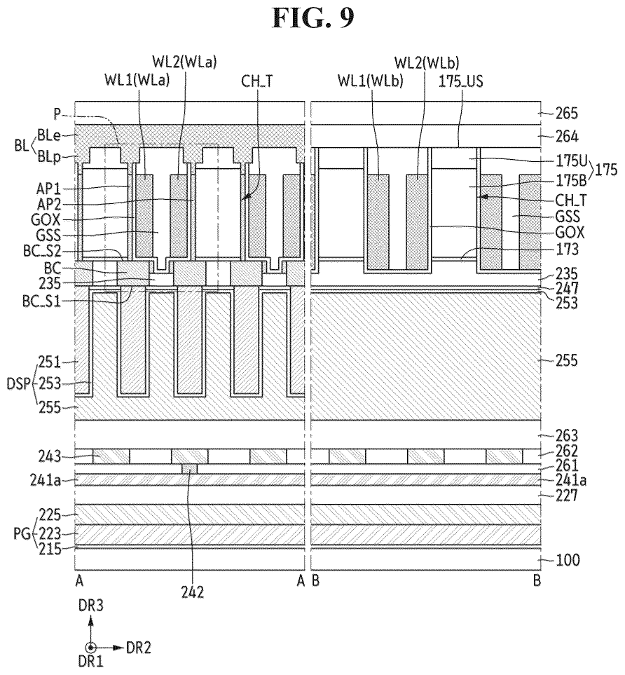

FIGS. 9 through 12 are cross-sectional or plan views for explaining a semiconductor memory device according to one or more embodiments of the present disclosure. For convenience of explanation, the embodiment of FIGS. 9 through 12 will hereinafter be described, focusing mainly on the differences from what has been described above with reference to FIGS. 1 through 8.

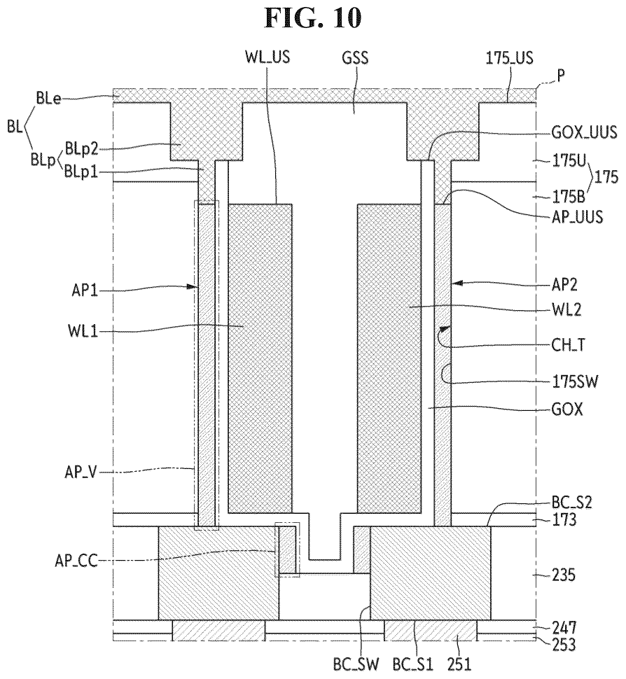

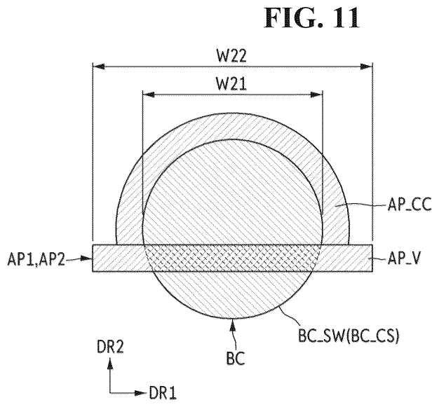

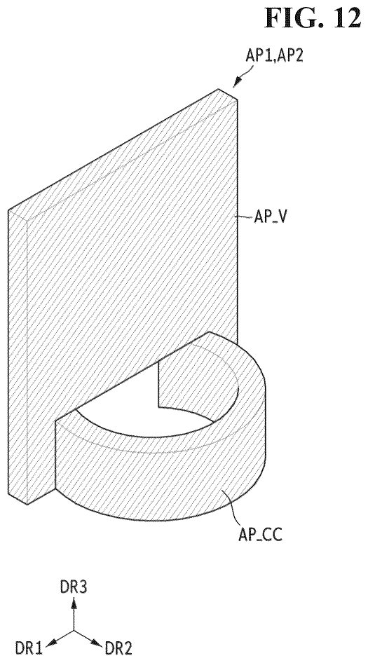

FIG. 9 is a cross-sectional view, taken along lines A-A and B-B of FIG. 2. FIG. 10 is an enlarged cross-sectional view of part P of FIG. 9. FIG. 11 is a plan view for explaining the shape in which channel patterns are disposed on contact patterns in FIG. 9. FIG. 12 is a perspective view for explaining the shape of the channel patterns of FIG. 11.

Referring to FIGS. 9 through 12, channel patterns (AP1 and AP2), in a semiconductor memory device according to one or more embodiments, first channel patterns AP1 and second channel patterns AP2 may include vertical portions AP_V and contact cover portions AP_CC.

The first channel patterns AP1 and the second channel patterns AP2 may not include the horizontal portions AP_H and bottom portions AP_B of FIG. 7.

The contact cover portions AP_CC of the channel patterns (AP1 and AP2) may be directly connected to the vertical portions AP_V of the channel patterns (AP1 and AP2). For the contact cover portions AP_CC of the channel patterns (AP1 and AP2) to be connected to the vertical portions AP_V of the channel patterns (AP1 and AP2), a width W22, in a first direction DR1, of the first channel patterns and the second channel patterns (AP1 and AP2) is greater than a width W21, in the first direction DR1, of second surfaces BC_S2 of contact patterns BC.

In a cross-sectional view such as FIG. 10, the horizontal portions AP_H of the channel patterns (AP1 and AP2) may not be disposed between a gate insulating film GOX and the contact patterns BC. The gate insulating film GOX may contact the second surfaces BC_S2 of the contact patterns BC.

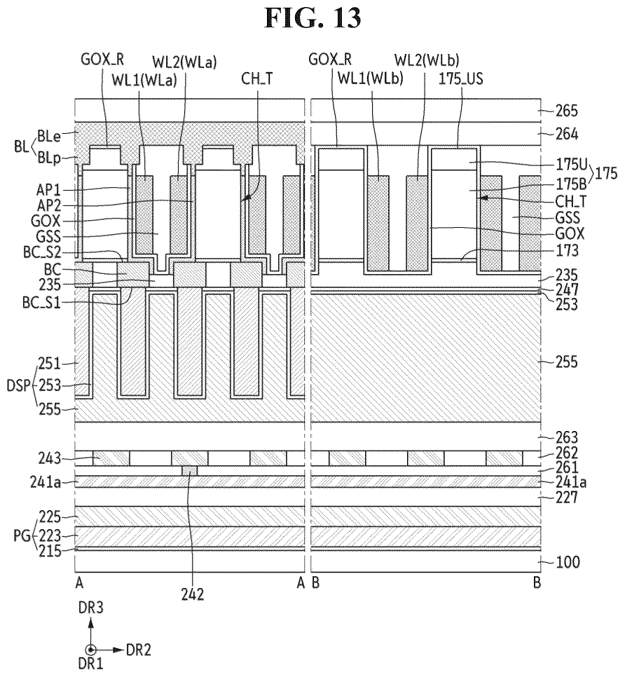

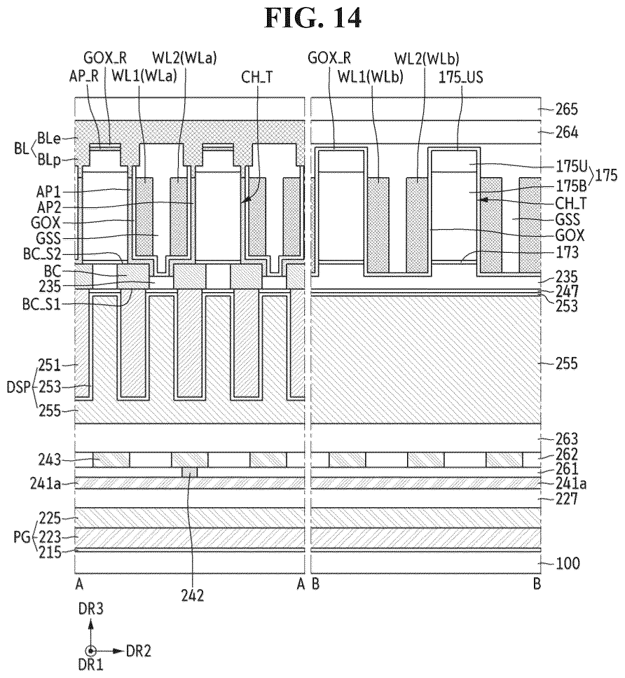

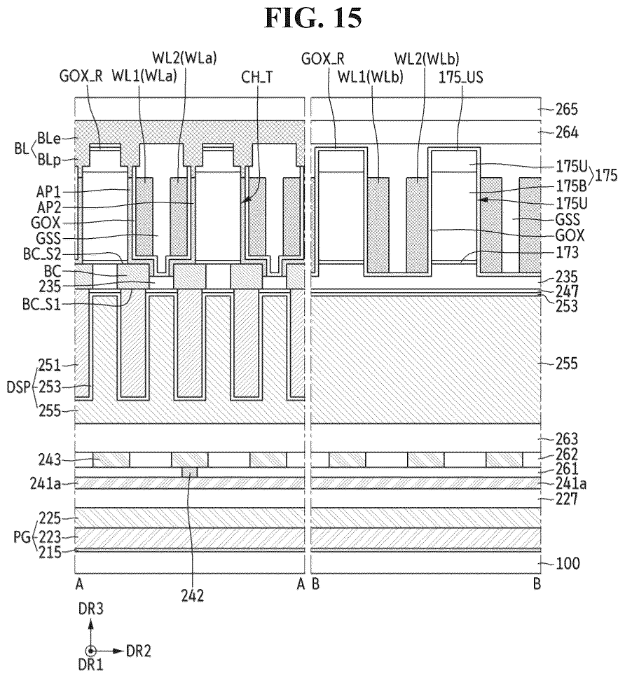

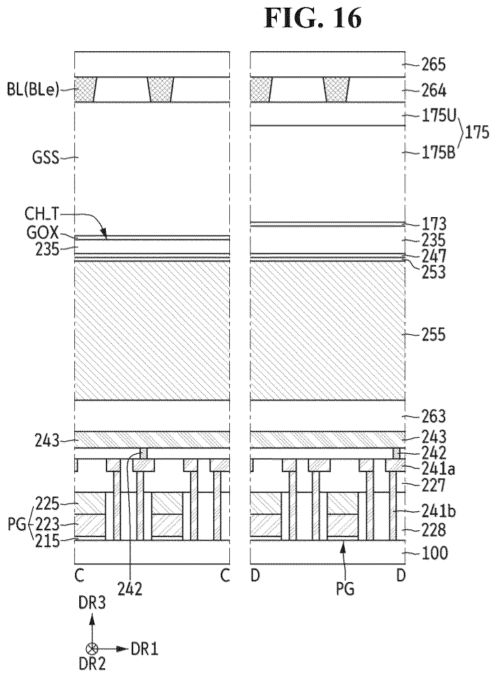

FIG. 13 is a cross-sectional view for explaining a semiconductor memory device according to one or more embodiments of the present disclosure. FIG. 14 is a cross-sectional view for explaining a semiconductor memory device according to one or more embodiments of the present disclosure. FIG. 15 is a cross-sectional view for explaining a semiconductor memory device according to one or more embodiments of the present disclosure. FIG. 16 is a cross-sectional view for explaining a semiconductor memory device according to one or more embodiments of the present disclosure. For convenience of explanation, the embodiments of FIGS. 13 through 16 will hereinafter be described, focusing mainly on the differences from what has been described above with reference to FIGS. 1 through 8.

FIGS. 13 through 15 are cross-sectional views taken along lines A-A and B-B of FIG. 2. FIG. 16 is a cross-sectional view taken along lines C-C and D-D of FIG. 2.

Referring to FIGS. 13 through 15, in the semiconductor memory devices according to one or more embodiments of the present disclosure, residual patterns GOX_R of a gate insulating film GOX may be disposed between protruding insulating patterns 175 and bitlines BL.

The residual patterns GOX_R of the gate insulating film GOX may extend along upper surfaces 175_US of protruding insulating patterns 175. The residual patterns GOX_R of the gate insulating film GOX may be directly connected to the gate insulating film GOX. In this case, the residual patterns GOX_R of the gate insulating film GOX may be portions of the gate insulating film GOX disposed on the upper surfaces 175_US of the protruding insulating patterns 175. The gate insulating film GOX may include portions disposed below the upper surfaces 175_US of the protruding insulating patterns 175.

The residual patterns GOX_R of the gate insulating film GOX may include the same material as the gate insulating film GOX.

In FIG. 13, the residual patterns GOX_R of the gate insulating film GOX may contact the bitlines BL and the protruding insulating patterns 175.

In FIG. 14, residual patterns AP_R of channel patterns (AP1 and AP2) may be disposed between the residual patterns GOX_R of the gate insulating film GOX and the protruding insulating patterns 175. The residual patterns AP_R of the channel patterns (AP1 and AP2) may include the same material as the channel patterns (AP1 and AP2).

In FIG. 15, parts of gate separation patterns GSS may be disposed on upper surfaces 175_US of protruding insulating patterns 175.

Referring to FIG. 16, a width, in a first direction DR1, of extension portions BLe of bitlines BL may increase away from protruding insulating patterns 175 and gate separation patterns GSS.

For example, the extension portions BLe of the bitlines BL may be formed through a damascene process.

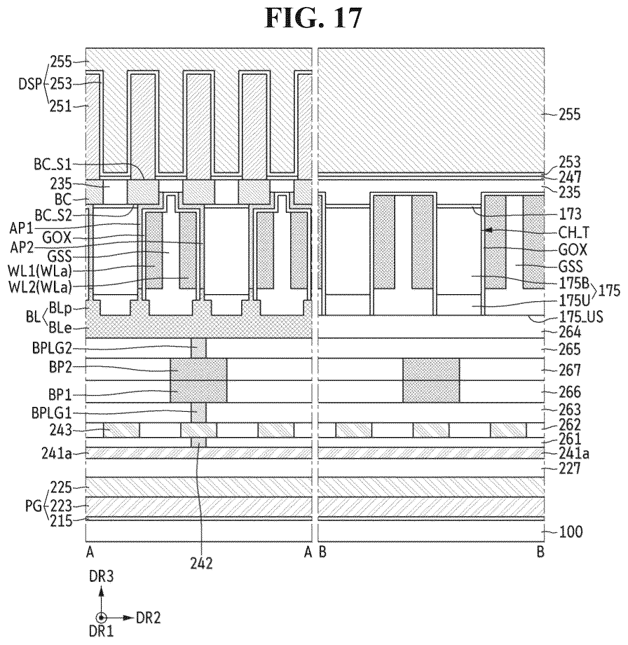

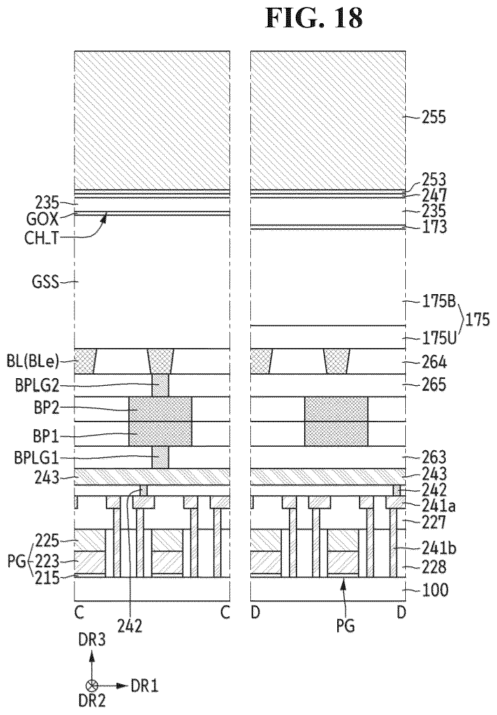

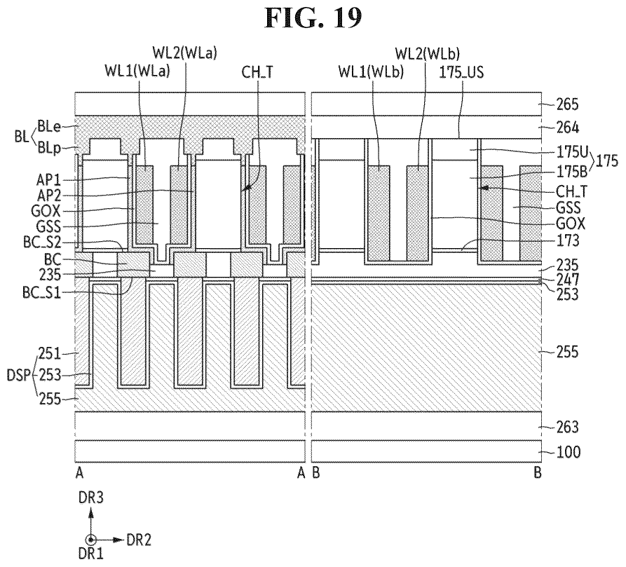

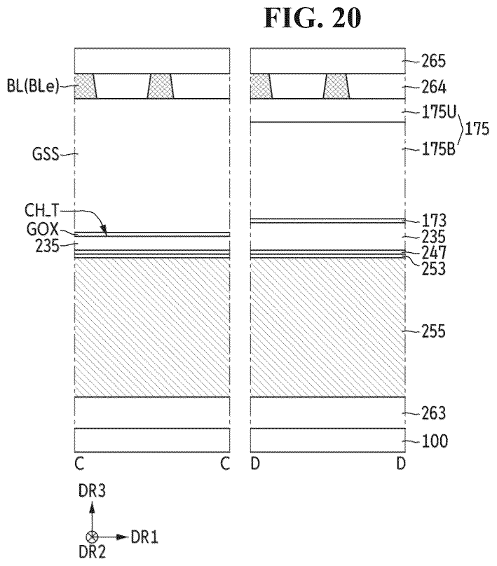

FIGS. 17 and 18 are cross-sectional views for explaining a semiconductor memory device according to one or more embodiments of the present disclosure. FIGS. 19 and 20 are cross-sectional views for explaining a semiconductor memory device according to one or more embodiments of the present disclosure. For convenience of explanation, the embodiments of FIGS. 17 through 20 will hereinafter be described, focusing mainly on the differences from what has been described above with reference to FIGS. 1 through 8.

Referring to FIGS. 17 and 18, the semiconductor memory device according to one or more embodiments of the present disclosure may further include first bonding pads BP1 and second bonding pads BP2.

The first bonding pads BP1 may be disposed on peripheral gate structures PG. The first bonding pads BP1 may be connected to peripheral connection wirings 243.

First pad plugs BPLG1 may be disposed between the first bonding pads BP1 and the peripheral connection wirings 243. The first pad plugs BPLG1 may connect the first bonding pads BP1 and the peripheral connection wirings 243.

The first pad plugs BPLG1 may be disposed within a first interlayer insulating film 263. The first bonding pads BP1 may be disposed within a fourth interlayer insulating film 266. The fourth interlayer insulating film 266 may be disposed on the first interlayer insulating film 263.

The second bonding pads BP2 may be disposed on the first bonding pads BP1. The second bonding pads BP2 may be connected to the first bonding pads BP1. The second bonding pads BP2 may contact the first bonding pads BP1.

Second pad plugs BPLG2 may connect the bitlines BL to the second bonding pads BP2. The second pad plugs BPLG2 may connect first wordlines WL1 and second wordlines WL2 to the second bonding pads BP2.

The second pad plugs BPLG2 may be disposed within a third interlayer insulating film 265. The second bonding pads BP2 may be disposed within a fifth interlayer insulating film 267. The fifth interlayer insulating film 267 may be disposed between the third interlayer insulating film 265 and the fourth interlayer insulating film 266. The fourth interlayer insulating film 266 may be disposed between the fifth interlayer insulating film 267 and the first interlayer insulating film 263.

The first pad plugs BPLG1 and the second pad plugs BPLG2 may each include a conductive material containing metal. The first bonding pads BP1 and the second bonding pads BP2 may each include a conductive material containing metal. The fourth and fifth interlayer insulating films 266 and 267 may each include an insulating material.

A bonding insulating film may be disposed along the boundaries of the first bonding pads BP1 and the second bonding pads BP2. For example, the bonding insulating film may include silicon carbonitride (SiCN). In another example, the bonding insulating film may include silicon oxide.

In the semiconductor memory device according to one or more embodiments of the present disclosure, the bitlines BL may be disposed between data storage patterns DSP and peripheral gate structures PG.

Referring to FIGS. 19 and 20, in the semiconductor memory device according to one or more embodiments of the present disclosure, peripheral gate structures PG may not be disposed in a cell array region CAR of a substrate 100.

The peripheral gate structures PG may be disposed only in a peripheral circuit region PCR of the substrate 100.

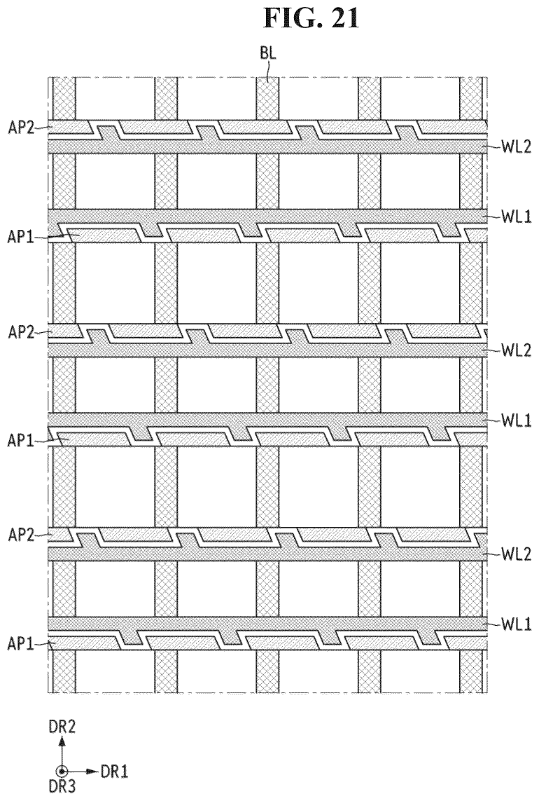

FIGS. 21 through 24 are layout views for explaining semiconductor memory devices according to one or more embodiments of the present disclosure. For convenience of explanation, the embodiments of FIGS. 21 through 24 will hereinafter be described, focusing mainly on the differences from what has been described above with reference to FIGS. 1 through 8.

Referring to FIG. 21, in the semiconductor memory device according to one or more embodiments of the present disclosure, first channel patterns AP1 and second channel patterns AP2 may be alternately arranged in a diagonal direction relative to a first direction DR1 and a second direction DR2. Here, the diagonal direction may be parallel to the upper surface of a substrate 100 as illustrated in FIG. 3.

The first channel patterns AP1 and the second channel patterns AP2 may be formed twisted in the diagonal direction. From a planar perspective, the first channel patterns AP1 and the second channel patterns AP2 may each have a parallelogram or rhomboid shape.

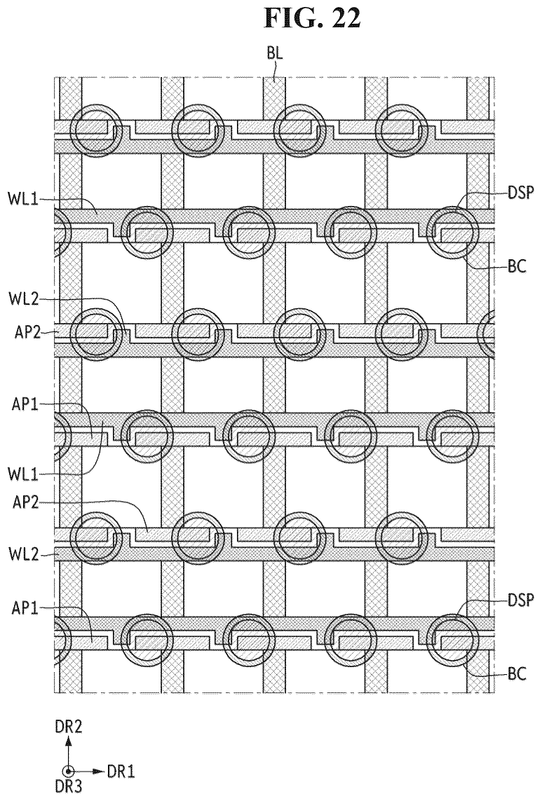

Referring to FIG. 22, in the semiconductor memory device according to one or more embodiments of the present disclosure, contact patterns BC and data storage patterns DSP may be arranged in a zigzag or honeycomb shape from a planar perspective.

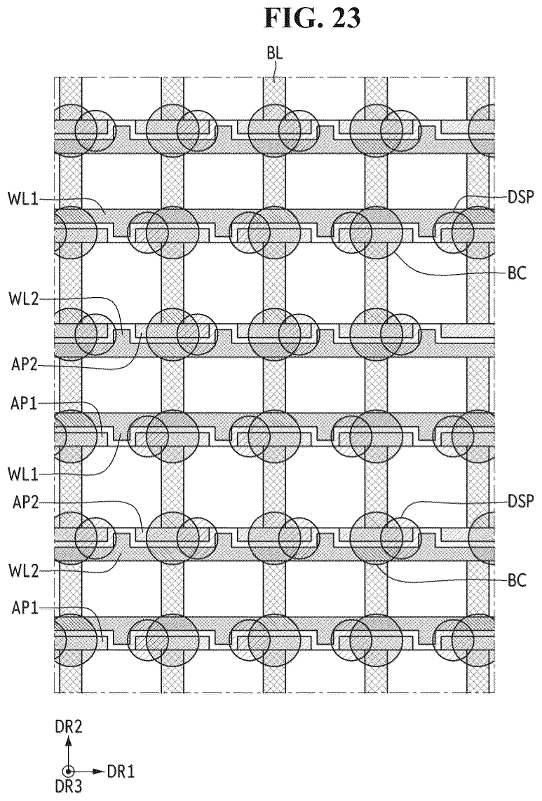

Referring to FIG. 23, in the semiconductor memory device according to one or more embodiments of the present disclosure, data storage patterns DSP may be arranged to deviate from contact patterns BC from a planar perspective.

The data storage pattern DSP may contact parts of the contact patterns BC.

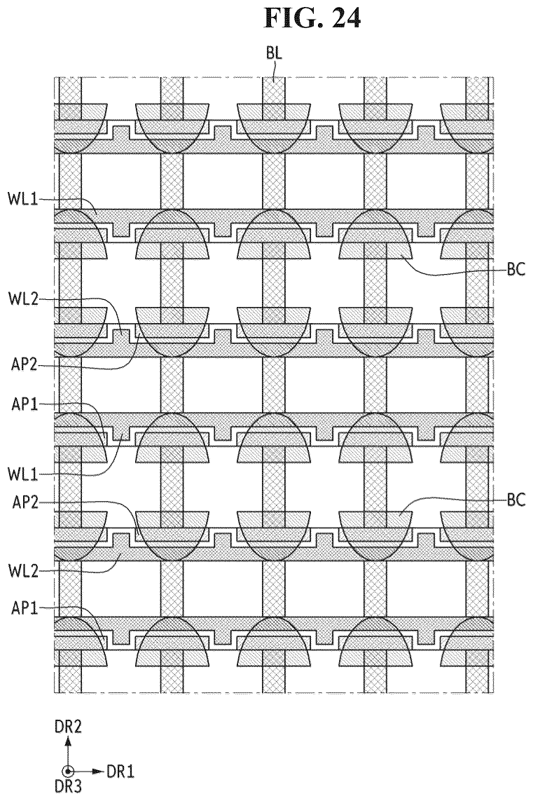

Referring to FIG. 24, in the semiconductor memory device according to one or more embodiments of the present disclosure, contact patterns BC, which are disposed on first channel patterns AP1 and second channel patterns AP2, may have a semicircular or semi-elliptical shape from a planar perspective.

From a planar perspective, the contact patterns BC may be arranged symmetrically to one another.

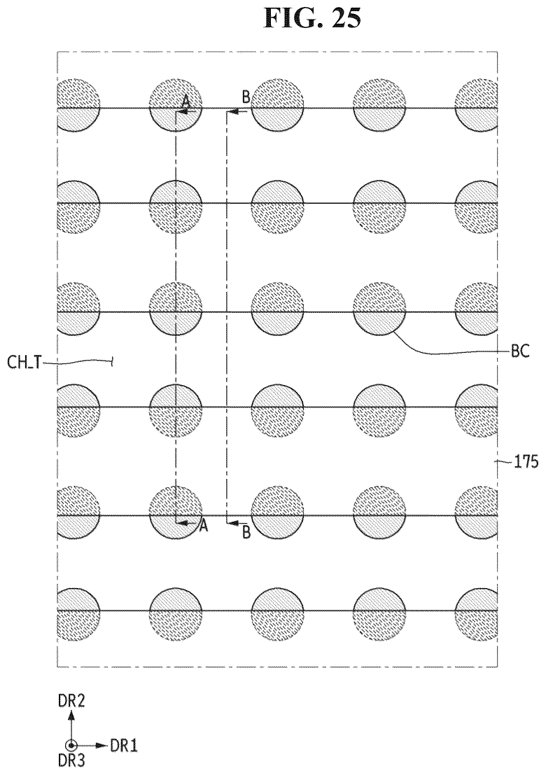

FIGS. 25 through 36 are cross-sectional views for explaining a method of manufacturing a semiconductor memory device according to one or more embodiments of the present disclosure.

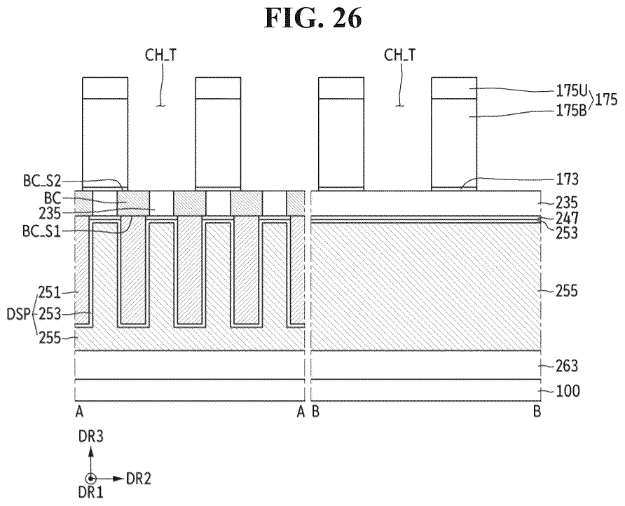

Referring to FIGS. 25 and 26, a contact separation insulating film 235 may be formed on a sub-substrate.

Contact patterns BC may be formed within the contact separation insulating film 235. The contact patterns BC may be formed on the sub-substrate.

Data storage patterns DSP may be formed on the contact patterns BC and the contact separation insulating film 235.

Thereafter, the sub-substrate on which the data storage patterns DSP and the contact patterns BC are formed may be bonded to a substrate 100. The data storage patterns DSP and the substrate 100 may be bonded by a first interlayer insulating film 263.

Alternatively, before the bonding of the sub-substrate to the substrate 100, peripheral gate structures PG as illustrated in FIG. 3 may be formed on the substrate 100. In this case, the sub-substrate on which the data storage patterns DSP and the contact patterns BC are formed may be bonded to the substrate 100 on which the peripheral gate structures PG are formed.

After the sub-substrate and the substrate 100 are bonded together, the sub-substrate may be removed.

Thereafter, protruding insulating patterns 175 may be formed on the contact patterns BC and the contact separation insulating film 235. Channel trenches CH_T may be formed within the protruding insulating patterns 175. The channel trenches CH_T may extend in a first direction DR1. As a result, the protruding insulating patterns 175, including channel trenches CH_T, may be formed on the contact patterns BC and the contact separation insulating film 235.

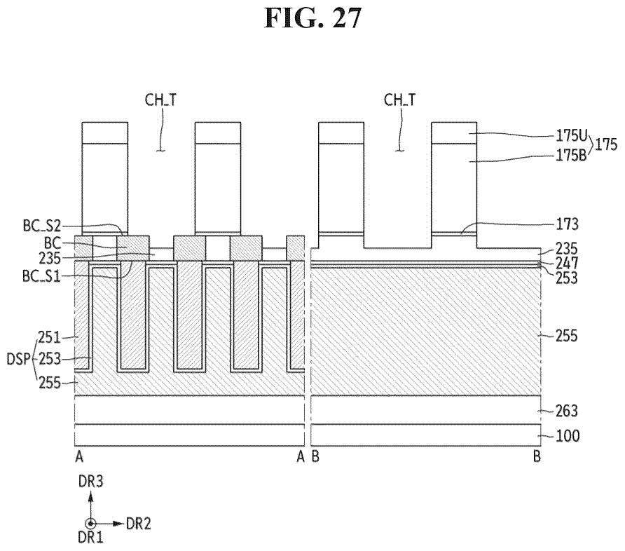

Referring to FIG. 27, parts of the contact separation insulating film 235 exposed by the channel trenches CH_T may be removed through an etching process.

During the etching process, parts of the sidewalls of the contact patterns BC overlapping with the channel trenches CH_T may be exposed.

In the areas where the contact separation insulating film 235 overlaps with the channel trenches CH_T in a third direction DR3, the thickness of the contact separation insulating film 235 may become thinner. As a result, parts of the sidewalls of the contact patterns BC may be exposed.

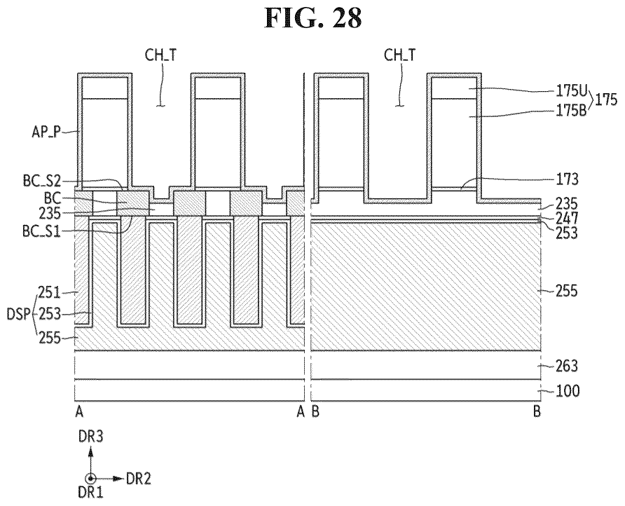

Referring to FIG. 28, a first channel film AP_P may be formed along the sidewalls and bottom surfaces of the channel trenches CH_T.

The first channel film AP_P may be formed along the upper surfaces of the protruding insulating patterns 175.

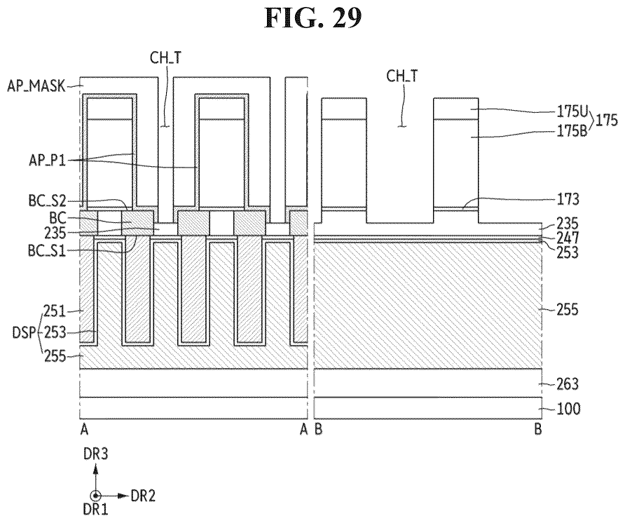

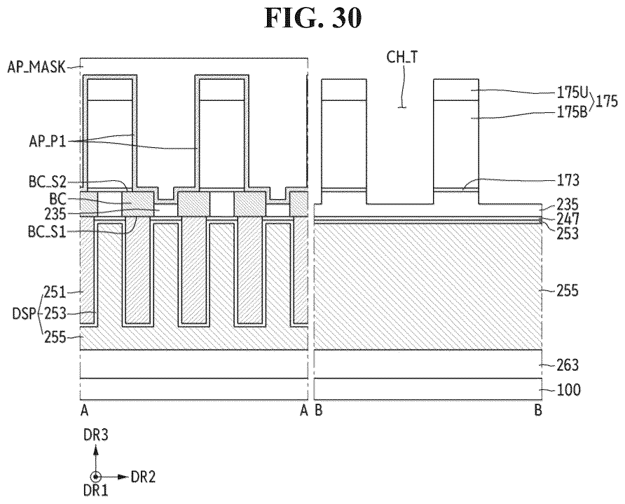

Referring to FIGS. 29 and 30, channel etching mask patterns AP_MASK may be formed on the first channel film AP_P of FIG. 28.

The first channel film AP_P may be patterned using channel etching mask patterns AP_MASK to form a second channel film AP_P1.

In FIG. 29, the channel etching mask patterns AP_MASK may have a contact-type shape. For example, from a planar perspective, the channel etching mask patterns AP_MASK may have a rectangular or square shape. The first channel film AP_P, which may be disposed between each pair of adjacent contact patterns BC in a second direction DR2 exposed by the channel trenches CH_T, may be removed. For example, from a planar perspective, the second channel film AP_P1 may have a rectangular or square shape.

In FIG. 30, the channel etching mask patterns AP_MASK may have a linear shape. For example, from a planar perspective, the channel etching mask patterns AP_MASK may have a linear shape extending in the second direction DR2. The channel etching mask pattern AP_MASK may intersect the channel trenches CH_T. The first channel film AP_P, disposed between each pair of adjacent contact patterns BC in the second direction DR2 exposed by the channel trenches CH_T, may not be removed. For example, from a planar perspective, the second channel film AP_P1 may have a linear shape extending in the second direction DR2. Referring to FIGS. 29 through 32, the channel etching mask patterns AP_MASK

are removed.

The channel etching mask patterns AP_MASK are removed, exposing the second channel films AP_P1.

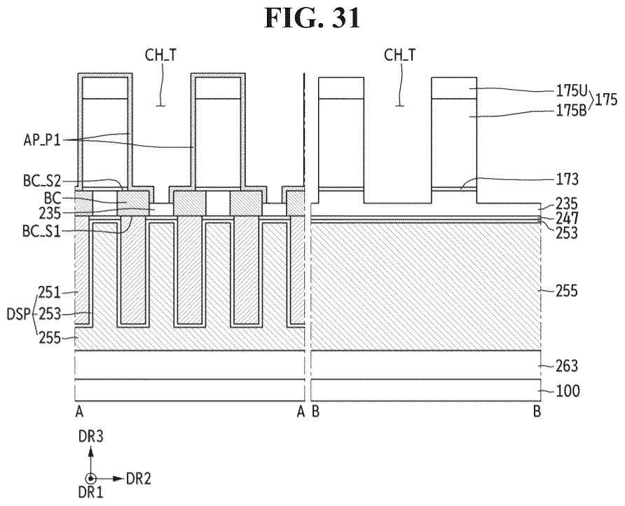

In FIGS. 29 and 31, the second channel film AP_P1 on one sidewall of each of the channel trenches CH_T may be separated from the second channel film AP_P1 on the opposite sidewall of each of the channel trenches CH_T.

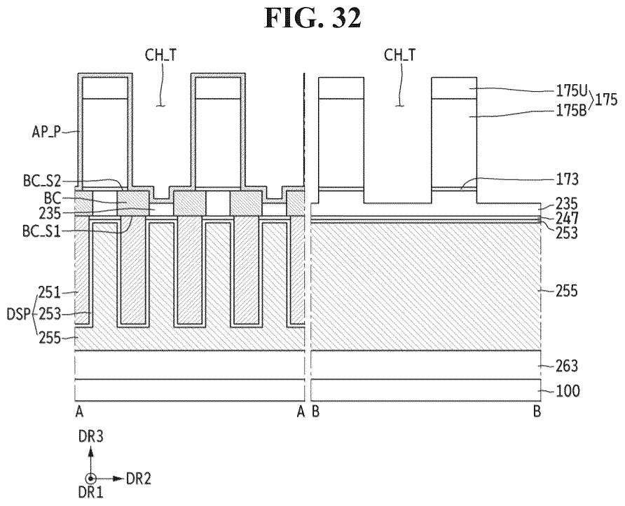

In FIGS. 30 and 32, the second channel film AP_P1 on one sidewall of each of the channel trenches CH_T may be directly connected to the second channel films AP_P1 on the opposite sidewall of each of the channel trenches CH_T.

Referring to FIGS. 31 through 34, the second channel film AP_P1 may be patterned to form first channel patterns AP1 and second channel patterns AP2 within the channel trenches CH_T.

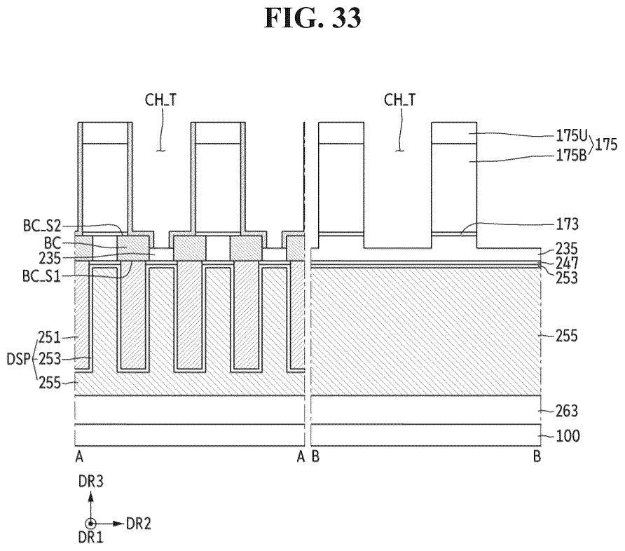

In FIGS. 31 and 33, sacrificial patterns may be formed within the channel trenches CH_T. The sacrificial patterns may expose the second channel film AP_P1 on the upper surfaces of the protruding insulating patterns 175. Using the sacrificial patterns as an etching mask, the second channel film AP_P1 may be removed from above the upper surfaces of the protruding insulating patterns 175. Through this process, the first channel patterns AP1 and the second channel patterns AP2, spaced apart from one another in the second direction DR2, may be formed within the channel trenches CH_T. After the first channel patterns AP1 and the second channel patterns AP2 are formed, the sacrificial patterns are removed.

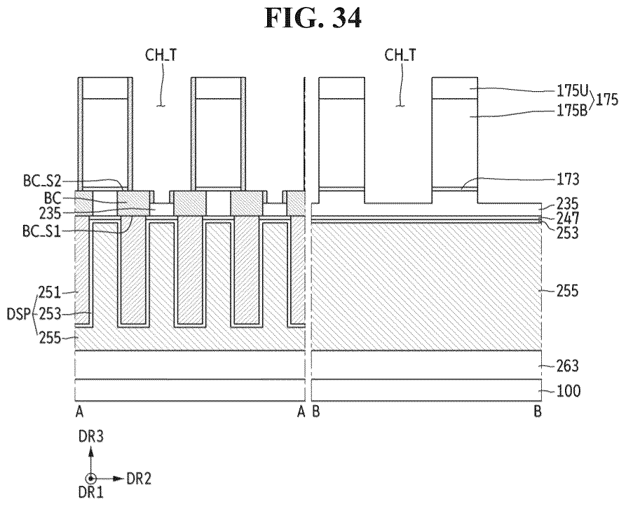

Referring to FIGS. 32 and 34, the second channel film AP_P1 may be removed from above the upper surfaces of the protruding insulating patterns 175 through an etch-back process. During the removal of the second channel film AP_P1 from above the upper surface of the protruding insulating pattern 175, the second channel film AP_P1 may also be removed from above second surfaces BC_S2 of contact patterns BC. Additionally, the second channel film AP_P1 may also be removed from above the second surface of the contact separation insulating film 235. As a result, the first channel patterns AP1 and the second channel patterns AP2, spaced apart in the second direction DR2, may be formed within the channel trenches CH_T.

Subsequent manufacturing process will be described using the shapes of the first channel patterns AP1 and the second channel patterns AP2 of FIG. 33.

Alternatively, the subsequent manufacturing processes may proceed with the second channel film AP_P1 remaining on the upper surfaces of the protruding insulating patterns 175. The resistance of channels, formed of a metal oxide semiconductor, increases in their off-state. Therefore, even if the second channel film AP_P1 remains on the upper surfaces of the protruding insulating patterns 175, it may not affect the operation of other memory cells.

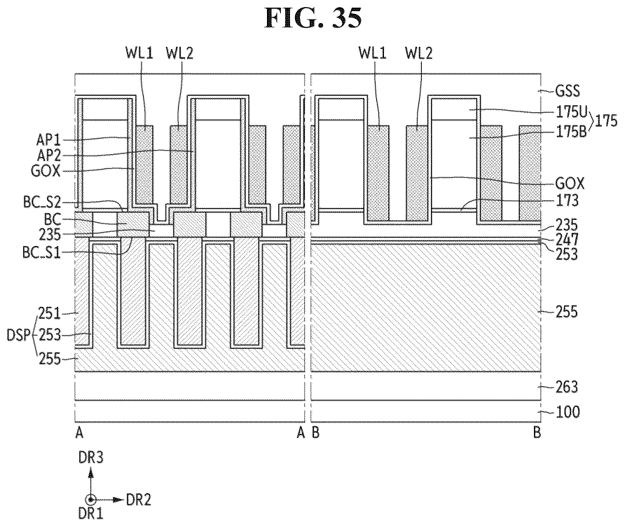

Referring to FIG. 35, a gate insulating film GOX may be formed on the first channel patterns AP1 and the second channel patterns AP2.

First wordlines WL1 and second wordlines WL2 may be formed on the gate insulating film GOX. The first wordlines WL1 and the second wordlines WL2 may be formed within the channel trenches CH_T of FIG. 33.

Thereafter, gate separation patterns GSS may be formed on the first wordlines WL1 and the second wordlines WL2. The gate separation patterns GSS may fill the channel trenches CH_T. Portions of the gate separation patterns GSS may be formed on the upper surfaces of the protruding insulating patterns 175.

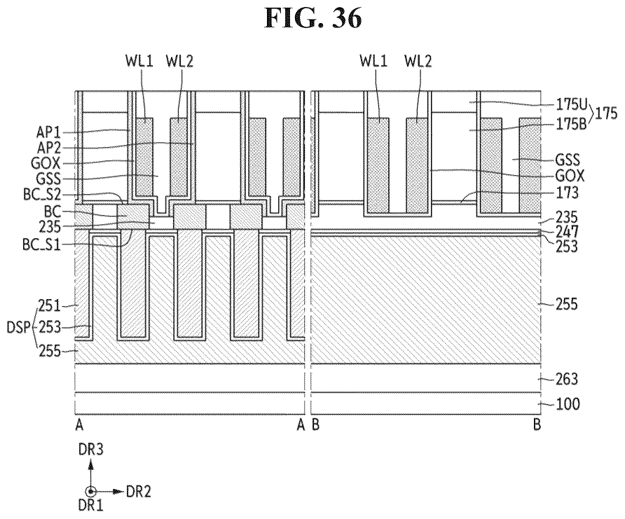

Referring to FIGS. 35 and 36, portions of the gate separation patterns GSS may be removed to expose the protruding insulating patterns 175.

While the protruding insulating patterns 175 are being exposed, the gate insulating film GOX may also be removed from above the upper surfaces of the protruding insulating patterns 175.

Thereafter, referring to FIG. 3, bitlines BL may be formed on the first channel patterns AP1 and the second channel patterns AP2.

Alternatively, the gate insulating film GOX may not be removed from above the upper surfaces of the protruding insulating patterns 175 while the protruding insulating patterns 175 are being exposed. With the gate insulating film GOX kept in place above the upper surfaces of the protruding insulating patterns 175, the bitlines BL may be formed on the first channel patterns AP1 and the second channel patterns AP2.

As another alternative, the bitlines BL may be formed on the first channel patterns AP1 and the second channel patterns AP2 without removing the gate separation patterns GSS from above the upper surfaces of the protruding insulating patterns 175.

Although the embodiments of the present disclosure have been described with reference to the accompanying drawings, the present disclosure is not limited to the above embodiments, and may be fabricated in various forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor memory device comprising:
a contact pattern comprising a first surface, a second surface, and a sidewall, wherein the first surface and the second surface are opposite to each other in a first direction, and the sidewall connects the first and the second surfaces;
a data storage pattern connected to the first surface;
a channel pattern on at least part of the sidewall, wherein the channel pattern is connected to the second surface;
a bitline on the channel pattern, wherein the bitline is connected to the channel pattern and extends in a second direction; and
a wordline on the channel pattern, wherein the wordline extends in a third direction.

2. The semiconductor memory device of claim 1, wherein the channel pattern comprises a vertical portion protruding in the first direction from the second surface and a contact cover portion on the at least part of the sidewall.

3. The semiconductor memory device of claim 2, wherein the contact cover portion extends along part of an outer circumferential surface of the contact pattern.

4. The semiconductor memory device of claim 2, wherein the channel pattern further comprises a horizontal portion extending along the second surface.

5. The semiconductor memory device of claim 4, further comprising:
a gate insulating film between the channel pattern and the wordline,
wherein the gate insulating film does not contact the second surface.

6. The semiconductor memory device of claim 2, further comprising:
a gate insulating film between the channel pattern and the wordline,
wherein the gate insulating film contacts the second surface.

7. The semiconductor memory device of claim 6, wherein a width, in the third direction, of the channel pattern is greater than a width, in the third direction, of the second surface.

8. The semiconductor memory device of claim 1, wherein the channel pattern does not extend to the first surface.

9. The semiconductor memory device of claim 1, further comprising:
a protruding insulating pattern on the second surface, the protruding insulating pattern comprising a channel trench,
wherein the channel pattern and the wordline are within the channel trench, and
wherein a height from the second surface to a lowermost portion of the bitline is less than a height from the second surface to an upper surface of the protruding insulating pattern.

10. The semiconductor memory device of claim 1,
wherein the bitline comprises an extension portion extending in the second direction and a protruding portion protruding in the first direction, and
wherein the protruding portion protrudes from the extension portion toward the channel pattern.

11. The semiconductor memory device of claim 10,
wherein the protruding portion of the bitline comprises a first sub-protruding portion and a second sub-protruding portion,
wherein the first sub-protruding portion contacts the channel pattern, and
wherein a width, in the second direction, of the first sub-protruding portion is greater than a width, in the second direction, of the second sub-protruding portion.

12. A semiconductor memory device comprising:
a contact pattern comprising a first surface and a second surface opposite to each other in a first direction;
a data storage pattern connected to the first surface;
a channel pattern connected to the second surface;
a bitline spaced apart from the contact pattern in the first direction, wherein the bitline is connected to the channel pattern and extends in a second direction; and
a wordline on the channel pattern and extending in a third direction,
wherein a height, in the first direction, of the channel pattern is greater than a height from the second surface to a lowermost portion of the bitline.

13. The semiconductor memory device of claim 12,
wherein the contact pattern comprises a sidewall connecting the first and the second surfaces, and
wherein the channel pattern extends along the sidewall in the first direction.

14. The semiconductor memory device of claim 12,
wherein the channel pattern comprises a vertical portion protruding in the first direction from the second surface, a horizontal portion extending along the second surface, and a contact cover portion on a sidewall of the contact pattern.

15. The semiconductor memory device of claim 12, further comprising:
a gate insulating film between the channel pattern and the wordline,
wherein the channel pattern comprises a vertical portion protruding in the first direction from the second surface and a contact cover portion on a sidewall of the contact pattern, and
wherein the gate insulating film contacts the second surface.

16. The semiconductor memory device of claim 12,
wherein the bitline comprises an extension portion extending in the second direction and a protruding portion protruding in the first direction, and
wherein the protruding portion protrudes from the extension portion toward the channel pattern.

17. The semiconductor memory device of claim 12, further comprising:
a gate insulating film between the channel pattern and the wordline,
wherein a height from the second surface to an uppermost portion of the channel pattern is less than a height from the second surface to an uppermost portion of the gate insulating film.

18. A semiconductor memory device comprising:
a peripheral gate structure on a substrate;
a contact pattern on the peripheral gate structure, the contact pattern comprising a first surface, a second surface, and a sidewall, wherein the first and the second surfaces are opposite to each other in a first direction, and wherein the sidewall connects the first and the second surfaces;
a data storage pattern connected to the first surface;
a channel pattern connected to the second surface, wherein the channel pattern is on a part of the sidewall;
a bitline on the channel pattern, wherein the bitline is connected to the channel pattern and extends in a second direction; and
a wordline on the channel pattern and extending in a third direction,
wherein the channel pattern comprises a vertical portion protruding in the first direction from the second surface, a horizontal portion extending along the second surface, and a contact cover portion on the sidewall.

19. The semiconductor memory device of claim 18, wherein the data storage pattern is between the peripheral gate structure and the bitline.

20. The semiconductor memory device of claim 18, wherein the bitline is between the peripheral gate structure and the data storage pattern.
